(19) United States
(12) Patent Application Publication
(10) Pub. No.: US 2019/0287770 A1
(43) Pub. Date: Sep. 19, 2019

(54) PLASMA PROCESSING APPARATUS

(71) Applicant: HITACHI HIGH-TECHNOLOGIES CORPORATION, Tokyo (JP)

(72) Inventors: Taku IWASE, Tokyo (JP); Tsutomu TETSUKA, Tokyo (JP); Kenetsu YOKOGAWA, Tokyo (JP)

(21) Appl. No.: 16/110,005

(22) Filed: Aug. 23, 2018

(30) Foreign Application Priority Data
Mar. 16, 2018 (JP) 2018-049014

(51) Int. Cl. H01J 37/32; H01L 21/67

(52) U.S. Cl. CPC H01J 37/32623; H01L 21/67069; H01J 37/3244; H01J 2237/3344; H01J 37/32715; H01J 37/32091; H01J 37/32834; H01J 37/32541

(57) ABSTRACT

A plasma processing apparatus improves uniformity of a plasma in a radial direction, generation efficiency of plasma, and a yield of a process, and the apparatus includes a sample stage which includes a dielectric susceptor ring located surrounding a top surface of the sample stage on an outer peripheral and a dielectric lower ring-shaped plate located at a position lower than a top surface of the susceptor ring on its outer peripheral side. A difference in height between the top surfaces of the lower ring-shaped plate and the sample is set in a range of around 5 mm of a value found by a formula using a distance: G [mm] between the upper and the lower electrodes, a frequency: f [MHz] of a first high-frequency power, and a pressure: P [Pa] in the processing chamber, and −0.1×G−0.06×f−4.4×ln(P)+22.

### CLAIM OF PRIORITY

The present application claims priority from Japanese Patent Application JP 2018-49014 filed on Mar. 16, 2018, the content of which is hereby incorporated by reference into this application.

### BACKGROUND

The present invention relates to a plasma processing apparatus that performs a process such as an etching using a plasma generated in a processing chamber on a film structure that includes a mask layer preliminarily formed on a top surface of a substrate-shaped sample such as a semiconductor wafer located in this processing chamber inside a vacuum container; and a film layer of a process target made of a material such as silicon oxide, silicon nitride, a low-dielectric film, polysilicon, and aluminum in a fabrication process of semiconductor devices. The present invention especially relates to a plasma processing apparatus that includes a sample stage located in the processing chamber to hold the sample on the top surface and a flat plate-shaped antenna or an electrode located above this top surface to form the plasma.

In a manufacturing process of semiconductor devices, plasma processing that performs processes such as an etching on a film layer of a process target on a semiconductor wafer by low-temperature plasma has been widely used. The low-temperature plasma, for example, applies a high-frequency power to a parallel plate type electrode that includes flat plate-shaped upper electrode and lower electrode located at a top and a bottom of a processing chamber inside a vacuum container under depressurization and opposed to one another to generate a capacitive coupling type plasma. Such parallel plate type plasma processing apparatus has been heavily used in the manufacturing process of semiconductor devices.

In the parallel plate type plasma processing apparatus, the semiconductor wafer is placed on a top surface of a sample stage above the flat plate-shaped lower electrode located inside the sample stage among the flat plate-shaped electrodes located at the top and bottom opposed to one another. Desired process gas is introduced into the processing chamber and then the high-frequency power is supplied to the upper electrode, which is located above the lower electrode opposed to the lower electrode, to generate the capacitive coupling type plasma. According to a difference between a bias potential and a plasma potential formed above the top surface of the semiconductor wafer on the lower electrode, charged particles such as ions and active species such as radicals in the plasma are induced and supplied to the semiconductor wafer surface. Thus, the film of the process target on the semiconductor wafer surface is processed. Such an etching by plasma allows regulating anisotropy of the process and therefore is advantageous in terms of process accuracy.

However, dimensions of circuits of the semiconductor devices have been steadily miniaturized and a request for accuracy of treatment performed by etching film layers constituting the circuit has also been increasing. Therefore, generating low-pressure, high-density plasma while an appropriate dissociation state of gas is maintained in the processing chamber has been demanded.

A frequency of the high-frequency power supplied to generate the plasma is generally 10 MHz or more, and the higher frequency is advantageous to generate the high-density plasma. However, since the high frequency shortens a wavelength of an electric field, this results in large non-uniformity of an electric field distribution in a plasma processing chamber.

The distribution of the electric field affects the electron density of the plasma, and the electron density affects an etch rate. Since degradation of an in-plane distribution of the etch rate lowers a mass-production, it has been demanded that the frequency of the high-frequency power is increased and uniformity of the etch rate in the wafer surface is increased.

Against such a problem, to increase the uniformity of the electron density of the plasma, a technique to regulate a path of the high-frequency power has been conventionally known. For example, Japanese Unexamined Patent Application Publication No. 2015-162266 (Patent Literature 1) has been known. The related art described in this Patent Literature 1 discloses the following configuration. A ring-shaped metallic confinement plate to which a ground potential has been set is located at a space between a sample stage, which is located at a lower side in a processing chamber inside a vacuum container, and a sidewall surface of the processing chamber surrounding the peripheral area outside the sample stage. To form plasma in the processing chamber, a current of a high-frequency power supplied to an upper electrode, which is located above a top surface of the sample stage, is flown in a return path, which passes through the metallic confinement plate from the top surface of the sample stage and passes through a member to which a ground potential is set and constituting the sidewall of the processing chamber, to return the current to a power source of the high-frequency power.

In the related art described in this Patent Literature 1 with the configuration, the plasma formed in the processing chamber between the top surface of the sample stage and the upper electrode is confined into a space upward with respect to the ring-shaped confinement plate. Additionally, the configuration achieves suppressing a distribution of an electric field in the processing chamber from being affected by an electric power passing through an electrostatic chuck inside the sample stage and a feeding path for a lower electrode.

Moreover, the plasma diffuses into and is distributed in the processing chamber of the plasma processing apparatus. Therefore, there has been a possibly that, in association with an increase in an accumulation value of a period during which a sample such as a semiconductor wafer is processed in the processing chamber or a period during which the plasma is generated in the processing chamber, an attachment of a substance derived from the plasma to apart of a surface other than a placement surface of the sample on the sample stage, consumption, and deterioration progress due to interaction with the plasma. Such a change in the surface in the processing chamber in association with a lapse of the time causes a problem of degradation of efficiency in generating the plasma and efficiency in the processes of the sample as a whole due to an increase in a period for cleaning to remove the deposit and cleaning by the plasma. For example, there has been conventionally known a technique disclosed in Japanese Unexamined Patent Application Publication No. Hei9(1997)-027396 (Patent Literature 2) as a technique to reduce a diffusion of the plasma and confine the plasma into a specific region in a processing chamber to solve such a problem.

### SUMMARY

The above-described related arts have generated problems due to insufficient consideration on the following points.

That is, although Patent Literature 1 improves uniformity of an electric field at a high-frequency power on a sample or a sample stage in a circumferential direction by a ring-shaped confinement plate, which constitutes a return route for plasma formation and is located on an outer peripheral side of the sample stage, Patent Literature 1 does not consider improvement in the uniformity in a radial direction. Furthermore, Patent Literature 2 uses a high-frequency power at a frequency in a range from 25 to 30 MHz and has not considered conditions and configurations to improve uniformity of a plasma distribution generated by a high-frequency power in a VHF band, which is a frequency bandwidth higher than 25 to 30 MHz.

In view of this, in the related arts described in Patent Literatures 1 and 2, a plasma processing apparatus, which generates a plasma in a processing chamber using the high-frequency power at the frequency in the VHF band, damages uniformity of a sample in a radial direction, possibly damaging a yield of a process. An object of the present invention is to provide a plasma processing apparatus that improves uniformity of a plasma in a radial direction, improves efficiency to generate the plasma, and improves a yield of a process.

In order to solve the above-described problems, the present invention provides a plasma processing apparatus that includes a processing chamber, a sample stage, a circular plate-shaped upper electrode, a shower plate, an upper ring-shaped plate, and a first high-frequency power supply. The processing chamber is located inside a vacuum container. A plasma is formed in a depressurized inside of the processing chamber. The sample stage is located at a lower portion in the processing chamber. The sample stage has a top surface on which a sample as a process target is placed and held. The circular plate-shaped upper electrode is located inside the processing chamber above the top surface of the sample stage so as to be opposed to the top surface. The shower plate is disposed at a side of the upper electrode. The side faces the sample stage. The shower plate has a multitude of introduction holes to supply the inside of the processing chamber with a gas for processing. The upper ring-shaped plate is made of a dielectric. The upper ring-shaped plate is located on an outer peripheral side of the shower plate. The upper ring-shaped plate constitutes a ceiling surface of the processing chamber. The first high-frequency power supply is configured to apply a first high-frequency power to the upper electrode. The sample stage includes a circular plate-shaped or cylindrical lower electrode, a susceptor ring, and a lower ring-shaped plate. The circular plate-shaped or cylindrical lower electrode is located inside the sample stage. A second high-frequency power is supplied to the circular plate-shaped or cylindrical lower electrode during processing the sample. The susceptor ring is made of a dielectric. The susceptor ring is located surrounding the top surface on an outer peripheral side of the top surface on which the sample is placed. The lower ring-shaped plate is made of a dielectric. The lower ring-shaped plate is located at a position lower than a top surface of the susceptor ring on an outer peripheral side of the susceptor ring. A distance between a top surface of the lower ring-shaped plate and a top surface of the sample in a height direction is set in a range of around 5 mm of a value found by a formula using a distance: G [mm] between the upper electrode and the lower electrode, a frequency: f [MHz] of the first high-frequency power, and a pressure: P [Pa] in the processing chamber, and −0.1×G−0.06×f−4.4×ln(p)+22 (Note that ln is a natural logarithm).

Moreover, in order to solve the above-described problems, the present invention provides a plasma processing apparatus that includes a vacuum container, a sample stage, an exhaust air unit, an upper electrode, and a high-frequency power application unit. The sample stage includes a placement surface and a susceptor ring. The susceptor ring is made of a dielectric surrounding a peripheral area of the placement surface. A sample is placed on the placement surface at a lower portion inside the vacuum container. The exhaust air unit is configured to exhaust an air inside the vacuum container. The upper electrode is located at an upper portion inside the vacuum container opposed to the sample stage. The upper electrode has a peripheral area covered with an insulator. The high-frequency power application unit is configured to apply a high-frequency power to the upper electrode. The plasma processing apparatus further includes a ring-shaped plate at an outer peripheral portion of the susceptor ring. The ring-shaped plate is made of a dielectric material with a relative permittivity of 80 or less. The ring-shaped plate is positioned lower than a top surface of the sample placed on the placement surface of the sample stage in a height direction. The ring-shaped plate is located at a position in the height direction such that a plasma with a density almost equivalent to a density at a top surface of the sample placed on the placement surface of the sample stage is formed when the high-frequency power is applied from the high-frequency power application unit to the upper electrode to generate a plasma at a space between the upper electrode and the sample stage inside the vacuum container.

The present invention ensures generating a plasma with an electron density of significantly high uniformity from an electrode center to an outer peripheral portion, ensures achieving an etch rate distribution of high uniformity in a wafer surface, and ensures improving a yield of a process.

### BRIEF DESCRIPTION OF THE DRAWINGS

FIG. 1 is a block diagram illustrating a schematic configuration of a plasma processing apparatus according to an embodiment of the present invention;

FIG. 2A is a plan view of a confinement plate of the plasma processing apparatus according to the embodiment of the present invention;

FIG. 2B is a plan view of a modification of the confinement plate of the plasma processing apparatus according to the embodiment of the present invention;

FIG. 3 is a graph illustrating a confinement plate relative permittivity dependence property of electron density uniformity in the plasma processing apparatus according to the embodiment of the present invention;

FIG. 4A is a cross-sectional view near an end portion on an upper side of a sample stage describing a difference h in height between a surface of a sample placed on the sample stage and a surface of the confinement plate in the plasma processing apparatus according to the embodiment of the present invention;

FIG. 4B is a graph illustrating a confinement plate position dependence property of the electron density uniformity in the plasma processing apparatus according to the embodiment of the present invention; and

FIG. 5 is a graph illustrating comparisons of electron density distributions between plasma processing apparatuses according to the embodiment of the present invention and according to comparative examples.

### DETAILED DESCRIPTION

The present invention restricts a high-density region of a plasma to enhance generation efficiency of the plasma and improve an etching rate even with an identical input electric power. Additionally, the present invention narrows a region where a deposit is accumulated to enhance cleaning efficiency in a chamber and lower an amount of foreign matter. Furthermore, an electron density distribution in the plasma is uniformized to improve uniformity of an etching rate distribution.

The following describes an embodiment of the present invention with reference to the drawings.

### EMBODIMENT

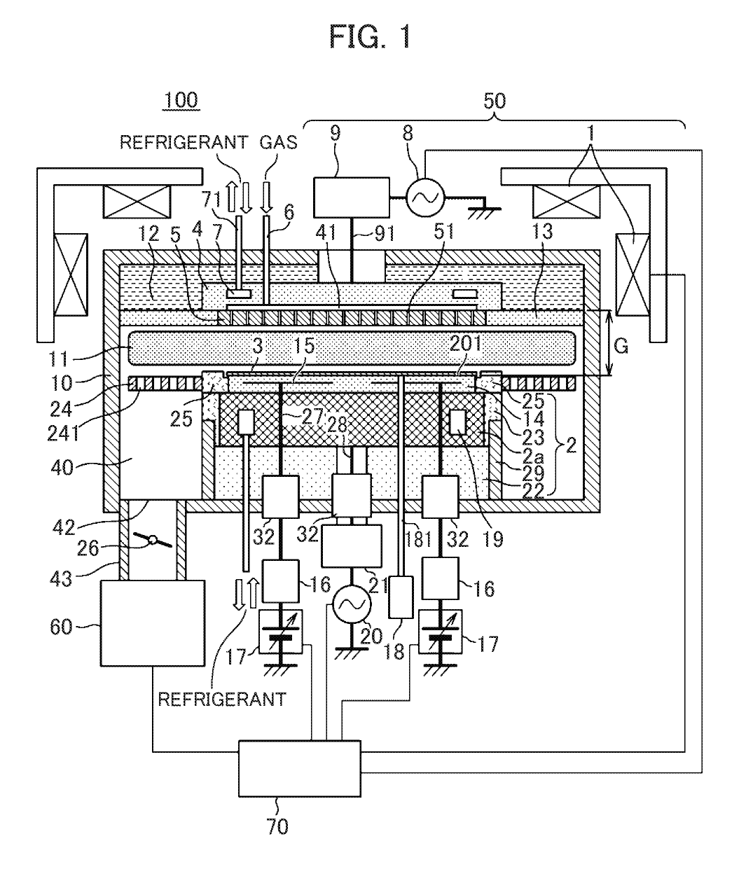

FIG. 1 is a vertical cross-sectional view schematically illustrating an outline of a configuration of a plasma processing apparatus 100 according to the embodiment of the present invention.

The plasma processing apparatus 100 according to FIG. 1 is an effective magnetic field parallel plate type plasma processing apparatus using electromagnetic coils 1 as solenoid coils. The plasma processing apparatus 100 of this embodiment includes a vacuum container 10, and a processing chamber 40 is formed in the plasma processing apparatus 100. The processing chamber 40 is a space inside this vacuum container 10, a sample as a process target is placed in the processing chamber 40, and gas for processing is supplied to the processing chamber 40 to form a plasma inside the processing chamber 40. Further, the plasma processing apparatus 100 includes a plasma forming unit 50 and an exhaust air unit 60. The plasma forming unit 50, which is located on the upper side of the vacuum container 10, is means to generate an electric field or a magnetic field to form the plasma inside the processing chamber 40. The exhaust air unit 60, which is coupled to the lower portion of the vacuum container 10, includes a vacuum pump such as a turbo molecular pump that exhausts air inside the processing chamber 40 for depressurization.

The processing chamber 40 of the vacuum container 10 internally includes a cylindrical sample stage 2 located at the lower side of the vacuum container 10. A substrate-shaped sample 3 such as a semiconductor wafer is placed on a placement surface 201, which is formed on the top surface of this sample stage 2. A circular plate-shaped upper electrode 4 to which a high-frequency power to form the plasma is supplied is disposed above this placement surface 201 arranged opposed to this placement surface 201. Additionally, a circular plate-shaped shower plate 5 is located on this upper electrode 4 opposed to the placement surface 201 of the sample stage 2 on the sample 3 side. The shower plate 5 has a plurality of through-holes 51 that constitute a ceiling surface of the processing chamber 40 to diffuse and supply the gas to the inside of this processing chamber 40.

A clearance 41 is formed between the shower plate 5 and the upper electrode 4, which is an antenna located on the upper side of the shower plate 5, with the shower plate 5 and the upper electrode 4 mounted to the vacuum container 10. The gas is introduced from a gas introduction line 6, which is located outside the vacuum container 10 and coupled to the clearance 41, to the clearance 41 via a gas flow channel disposed in the upper electrode 4. The gas supplied to the clearance 41 is dispersed at the inside of the clearance 41. Subsequently, the gas passes through the plurality of through-holes 51, which are located at regions including the center on the shower plate 5 side, and is supplied to the inside of the processing chamber 40.

The gas passing through the plurality of through-holes 51 and supplied to the inside of the processing chamber 40 includes, for example, a gas for processing used for a process of the sample 3 or an inert gas. Although not directly used for the process, the inert gas dilutes the gas for processing and is supplied to the inside of the processing chamber 40 while the gas for processing is not supplied and replaced by the gas for processing.

An upper electrode refrigerant flow channel 7 is formed inside the upper electrode 4. A refrigerant supply line 71 coupled to a temperature control device (not illustrated) such as a chiller, which adjusts a temperature of a refrigerant in a predetermined range, is coupled to this upper electrode refrigerant flow channel 7. The refrigerant whose temperature has been adjusted in the predetermined range is supplied from the temperature control device (not illustrated) via the refrigerant supply line 71 to the inside of the upper electrode refrigerant flow channel 7 for circulation. Thus performing heat exchange adjusts the temperature of the upper electrode 4 within a range of a value appropriate for the process.

The upper electrode 4 is formed of a circular plate-shaped member made of aluminum, stainless steel, or the like as a conductive material. A coaxial cable 91 to which a high-frequency power for plasma formation is transmitted is electrically connected to the center of the top surface of the upper electrode 4. The high-frequency power for plasma formation is supplied from a high frequency power supply for discharge 8 (hereinafter referred to as a high-frequency power supply 8), which is electrically connected to the upper electrode 4 via the coaxial cable 91, to the upper electrode 4 via a high-frequency power matching box for discharge 9. The high-frequency power for plasma formation transmits from the surface of the upper electrode 4 to the shower plate 5, and the electric field is discharged to the inside of the processing chamber 40. This embodiment uses the electric power at 200 MHz, a frequency in a very high frequency band (a VHF band) as the high-frequency power for plasma formation applied from the high-frequency power supply 8 to the upper electrode 4.

Furthermore, the electromagnetic coils 1 are located outside the vacuum container 10 and at positions surrounding an upper side and a lateral side of the upper portion of the processing chamber 40. The magnetic field generated by these electromagnetic coils 1 is formed inside the processing chamber 40.

The shower plate 5 is made of a dielectric such as quartz and a semiconductor such as silicon. This allows the electric field formed by the upper electrode 4 to transmit the shower plate 5 in the state where the high-frequency power supply 8 applies the high-frequency power for plasma formation to the upper electrode 4.

The upper electrode 4 is electrically insulated from the vacuum container 10 by a ring-shaped upper electrode insulator 12, which is located at the upper side and the lateral sides of the upper electrode 4 and made of a dielectric such as quartz and Teflon (registered trademark). Similarly, an insulating ring 13 made of a dielectric such as quartz is located at the peripheral area of the shower plate 5 for insulation of the shower plate 5 from the vacuum container 10. These upper electrode insulator 12, insulating ring 13, upper electrode 4, and shower plate 5 are fixed to a lid member (not illustrated), which constitutes the upper portion of the vacuum container 10, and turn integrally with the lid member when the lid member is operated to be opened/closed.

The cylindrical vacuum container 10 has a sidewall coupled to a conveying container as a vacuum container (not illustrated). The sample 3 is conveyed through a decompressed inside of the conveying container. Between these members, a gate as an opening of a passage where the sample 3 is put in and taken out is located. A gate valve that airtightly seals the inside of the vacuum container 10 by blocking the gate when the sample 3 is processed at the inside of the vacuum container 10 is located.

An exhaust air opening 42 that communicates with the exhaust air unit 60, which exhausts the air inside the processing chamber 40, is located at the lower side of the sample stage 2 inside the processing chamber 40 and at the lower portion of the vacuum container 10. Between this exhaust air opening 42 and a vacuum pump (not illustrated) of the exhaust air unit 60, a pressure regulating valve 26 as a plate-shaped valve is located at the inside of an exhaust air path 43, which couples these members. This pressure regulating valve 26 is a plate-shaped valve located across the cross-sectional surface of the exhaust air path 43. An axial rotation of this plate-shaped valve increases and decreases the cross-sectional area of the flow channel.

Adjusting the angle of the rotation of the pressure regulating valve 26 allows increasing and decreasing a flow rate or a speed of the exhaust of air from the processing chamber 40. A control unit 70 adjusts the pressure inside the processing chamber 40 so as to be in a range of a desired value by a balance between the flow rate or the speed of the gas supplied from the through-holes 51 on the shower plate 5 and the flow rate or the speed of the gas and particles discharged from the exhaust air opening 42 to the exhaust air unit 60 side.

Next, the following describes a structure around the sample stage 2. The sample stage 2 of this embodiment is a cylindrical-shaped stage located at the center on the lower side of the processing chamber 40 and internally includes a cylindrical or circular plate-shaped metallic base material 2a.

The base material 2a of this embodiment is electrically connected to a high frequency power supply for bias 20 by a feeding path 28 including a coaxial cable via a high frequency power matching box for bias 21, which is located on this feeding path 28. A high frequency power for bias applied from the high frequency power supply for bias 20 to the base material 2a has a frequency (4 MHz in this example) different from the high frequency power for plasma formation applied from the high-frequency power supply 8 to the upper electrode 4. Additionally, an element 32 such as a resistor or a coil is located on the feeding path 28, and this element 32 is coupled to the grounded high frequency power matching box for bias 21 and high frequency power supply for bias 20.

Supplying the base material 2a with the high-frequency power from the high frequency power supply for bias 20 while the high-frequency power supply 8 applies the high frequency power for plasma formation to the upper electrode 4 to generate a plasma 11 between the sample stage 2 and the shower plate 5 generates a bias potential in the base material 2a. This bias potential induces charged particles such as ions in the plasma 11 to the top surface of the sample 3 or the placement surface 201. That is, the base material 2a functions as a lower electrode to which the high frequency power for bias is applied below the upper electrode 4.

Multiple refrigerant flow channels 19 are concentrically or spirally located inside the base material 2a. The refrigerant flow channels 19 circulate and flow a refrigerant adjusted to a predetermined temperature by the temperature control device such as the chiller (not illustrated).

An electrostatic adsorption film 14 is located on the top surface of the base material 2a. The electrostatic adsorption film 14 is made of a material of a dielectric such as alumina or yttria and contains tungsten electrodes 15 to which a DC power for electrostatic adsorption of the sample 3 is supplied. Feeding paths 27 located passing through the base material 2a are coupled to the back surfaces of the tungsten electrodes 15. The tungsten electrodes 15 are electrically connected to DC power supplies 17 by these feeding paths 27 via the elements 32 such as resistors or coils and the grounded low-pass filters 16.

Terminals on one end side of the DC power supplies 17 and the high frequency power supply for bias 20 of this embodiment are grounded or electrically connected to a grounding wire.

The low-pass filters 16, which filter by blocking a flow of a current at a higher frequency, and the high frequency power matching box for bias 21 are located so as to reduce flowing of the high-frequency power for plasma formation from the high-frequency power supply 8 into the DC power supplies 17 and the high frequency power supply for bias 20.

While the DC power from the DC power supplies 17 or the high-frequency power from the high frequency power supply for bias 20 are supplied to the electrostatic adsorption film 14 and the sample stage 2 without a loss, respectively, the high-frequency power for plasma formation flown from the sample stage 2 side to the DC power supplies 17 and the high frequency power supply for bias 20 is flown to the grounding wire via the low-pass filters 16 or the high frequency power matching box for bias 21. Although the low-pass filters 16 are not illustrated on the feeding path 28 from the high frequency power supply for bias 20 of FIG. 1, a circuit having the similar effect is built into the illustrated high frequency power matching box for bias 21.

In such a configuration, an impedance of the electric power from the high-frequency power supply 8 when the side of the DC power supplies 17 and the high frequency power supply for bias 20 is viewed from the sample stage 2 is configured to be relatively low. In this embodiment, the elements 32 such as the resistors or the coils that increase the impedance are inserted and arranged between the electrode, and the low-pass filters 16 and the high frequency power matching box for bias 21 on the feeding paths. Thus, the impedance of the high-frequency power for plasma formation of the side of the DC power supplies 17 or the high frequency power supply for bias 20 viewed from the base material 2a side of the sample stage 2 is configured to be high (100Q or more in this embodiment).

The embodiment illustrated in FIG. 1 includes the plurality of tungsten electrodes 15 located inside the electrostatic adsorption film 14. A bipolar electrostatic adsorption to which a DC voltage is supplied such that one among these tungsten electrodes 15 and the other have different polarities is performed. In view of this, the tungsten electrodes 15 are divided into two regions having different polarities by halving the area of the surface of the electrostatic adsorption film 14, which forms the placement surface 201, in contact with the sample 3 or with values in a range approximated to the extent regarded as this. Thus, the respective DC powers with values independent from one another are supplied, and the voltages are maintained to have the different values.

Helium gas is supplied between the electrostatic adsorption film 14 and the back surface of the sample 3 in contact by the electrostatic adsorption from helium supply unit 18 via a pipe 181. This ensures improving efficiency of heat transmission between the sample 3 and the electrostatic adsorption film 14 and increasing an amount of heat exchange between the inside of the base material 2a and the refrigerant flow channels 19, thus enhancing efficiency to adjust the temperature of the sample 3.

A circular plate-shaped insulating plate 22 made of Teflon or a similar material is located below the base material 2a. Accordingly, the base material 2a grounded or electrically connected to the ground to be set to the ground potential is electrically insulated from the members constituting the lower side of the processing chamber 40. Furthermore, a ring-shaped insulating layer 23 made of a dielectric such as alumina is located at the peripheral area of the side surface of the base material 2a so as to surround the base material 2a.

A conductive plate 29 is located at the peripheral area of the insulating plate 22, which is located below the base material 2a coupled to the base material 2a, and at the peripheral area of the insulating layer 23, which is located above the insulating plate 22 so as to surround the base material 2a. The conductive plate 29, which is made of a conductive material, is grounded or electrically connected to the ground to be set to a ground potential. The conductive plate 29 is a plate member having a circular shape viewed from the above or the similar shape to the extent of being regarded as the circular shape. The insulating layer 23 is interposed between the conductive plate 29 and the base material 2a, and the conductive plate 29 and the base material 2a are electrically insulated.

A susceptor ring 25 made of a dielectric such as quartz or a semiconductor such as silicon is located at the upper side of the ring-shaped insulating layer 23. The susceptor ring 25 is located at the peripheral area of the sample 3 and the base material 2a is covered with the susceptor ring 25 and the insulating layer 23. This regulates a distribution of a reaction product around the outer end portion of the sample 3 to uniformize process performance.

Thus, the sample stage 2 includes the base material 2a, the electrostatic adsorption film 14, which internally includes the tungsten electrodes 15, the insulating plate 22 on which the base material 2a is placed for electrical insulation between the base material 2a and the vacuum container 10, the insulating layer 23, which is made of the insulating material and surrounds the peripheral area of the base material 2a, the susceptor ring 25, which covers the top surface of the base material 2a and the side surface of the electrostatic adsorption film 14, and the conductive plate 29, which covers the outer peripheral portion of the insulating plate 22 and the outer peripheral portion of the insulating layer 23.

A plate-shaped confinement plate 24 is concentrically mounted on the outer peripheral side of the susceptor ring 25 located so as to be in contact with the susceptor ring 25. The confinement plate 24 is to prevent the generation region of the plasma 11 formed inside the processing chamber 40 from enlarging up to the side surface of the sample stage 2 and biases the generation region to the upper portion of the sample stage 2, that is to say, located for confinement. The plate-shaped confinement plate 24 has a plurality of holes 241 or slits 242 to cause the gas and the particles to pass through in an up-down direction.

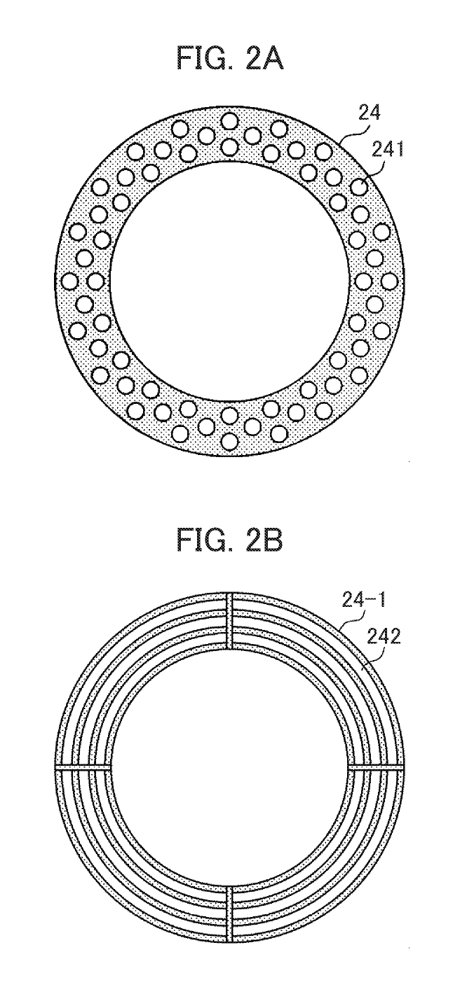

FIG. 2A and FIG. 2B illustrate plan views of the confinement plate 24.

FIG. 2A illustrates a configuration of a confinement plate where the confinement plate 24 evenly has the holes 241. FIG. 2B illustrates a configuration of a confinement plate where a confinement plate 24-1 equally has the slits 242 and parts between the respective slits 242 are supported at a plurality of sites. This embodiment employs the configuration of FIG. 2A. The confinement plate 24 is preferably made of a dielectric, and a degree of the uniformity of the process performance changes depending on a relative permittivity of a material constituting the dielectric.

In such a configuration, in a state where the gas for processing or the inert gas is supplied from the plurality of through-holes 51 on the shower plate 5 to the inside of the processing chamber 40 while the exhaust air unit 60 exhausts the air at the inside of the processing chamber 40, the electromagnetic coils 1 form the magnetic field at the inside of the processing chamber 40, and the high-frequency power is applied from the high-frequency power supply 8 to the upper electrode 4. This excites atoms or molecules in the gas for processing or the inert gas, and the plasma 11 is formed at the inside of the processing chamber 40.

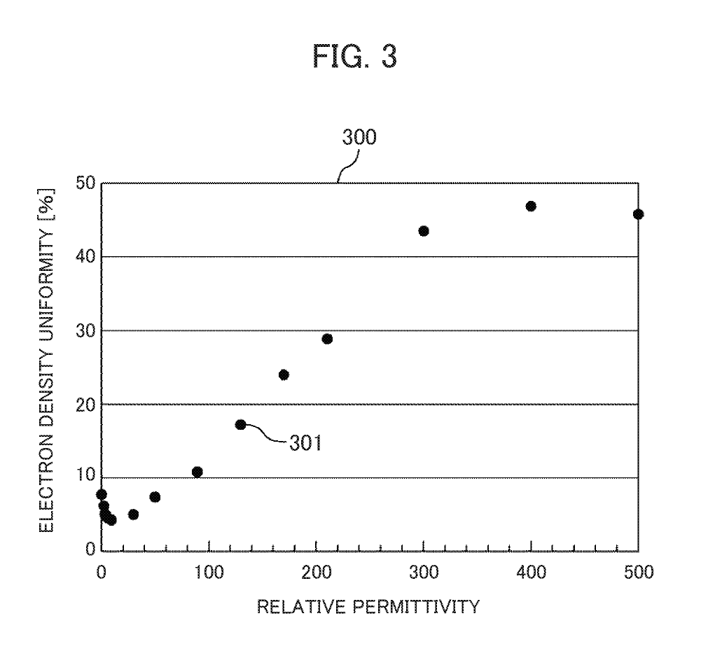

A graph 300 illustrated in FIG. 3 illustrates a relationship between a relative permittivity of the material constituting the confinement plate 24 and electron density uniformity of the plasma in the radial direction. Respective black dots 301 in the graph 300 indicate the distribution of the electron density of the plasma in the radial direction generated when the confinement plate 24 is made of a material having a certain relative permittivity. Here, the electron density uniformity on the vertical axis indicates a result of analyzing the electron density distribution of the plasma based on the configuration of this embodiment and deriving the uniformity in the middle between the sample 3 placed on the sample stage 2 and the shower plate 5 in a range up to 230 mm from the center of the vacuum container 10 (the center of the sample stage 2) toward the inner wall of the processing chamber 40 by percentage. In the case where the relative permittivity of the material constituting the confinement plate 24 is high, since bringing the confinement plate 24 into contact with the plasma 11 facilitates polarization, the electric potential of the wall becomes high and a sheath thickens.

When a distance between the electrodes, which is between the upper electrode 4 covered with the shower plate 5 and the sample stage 2, is configured to be constant, thickening the sheath generally lowers the electron density of the plasma. Lowering the electron density in the region of the confinement plate 24 degrades the electron density uniformity in a region from the top surface of the sample 3 attracted to the electrostatic adsorption film 14 to the top surface of the confinement plate 24.

When a yardstick of the uniformity of the electron density distribution in this region is defined as 10%, it is seen from FIG. 3 that, to configure the electron density uniformity to be 10% or less, the material with the relative permittivity of 80 or less needs to be used for the confinement plate 24. The material meeting such a condition includes, for example, quartz (SiO₂), alumina (Al₂O₃), and yttria (Y₂O₃). This embodiment uses the quartz.

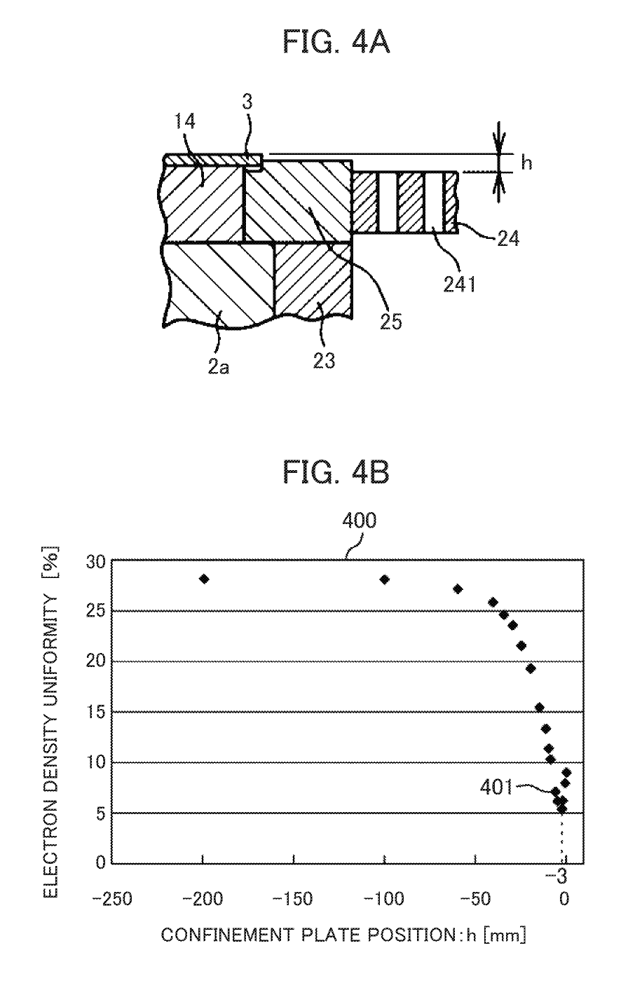

The installation position of the confinement plate 24 has a preferable range in the configuration of the plasma processing apparatus of this embodiment. As illustrated in FIG. 4A, with the height of the top surface of the sample 3 placed on the electrostatic adsorption film 14 of the sample stage 2 as a criterion, a relative position (a difference in height) to the top surface of the confinement plate 24 is defined as h. For example, when the top surface of the confinement plate 24 is lower than the top surface of the sample 3 by 1 mm, h=−1 mm.

FIG. 4B illustrates the confinement plate position h dependence property of the electron density uniformity of the plasma in the radial direction. The height (the difference in height between the surface of the sample 3 and the confinement plate 24: h) of the confinement plate 24 changes the volume of the plasma confined between the electrodes between the upper electrode 4 covered with the shower plate 5 and the sample stage 2. The change in the volume of the plasma varies the electron density.

It is seen that, as illustrated in FIG. 4B, the configuration of this embodiment exhibits the best electron density uniformity with the position h of the confinement plate 24=−3 mm. It has been found that the preferable value of the height (the position) h of this confinement plate 24 is mainly affected by a pressure P (Pa) in the processing chamber 40, the gap distance between the upper/lower electrodes (the interval between the surface of the upper electrode 4 opposed to the sample stage 2 and the surface of the electrostatic adsorption film 14 of the sample stage 2 opposed to the upper electrode 4) G [mm], and the discharge frequency f [MHz].

As a result of analytically obtaining a correlation between the electron density distribution and an apparatus parameter, performing scaling so as to increase the uniformity, and deriving the height, it has been found out that the height can be expressed by following formula. Note that ln in the following formula indicates a natural logarithm.

h=−0.1×G−0.06×f−4.4×ln(P)+22 (Expression 1)

Furthermore, it has also been found out from FIG. 4B that, to configure the uniformity of the electron density so as to be 10% or less, h only needs to be within a range of ±5 mm of the value obtained by (Expression 1). In this embodiment, G=40 mm, P=8 Pa, and f=200 MHz.

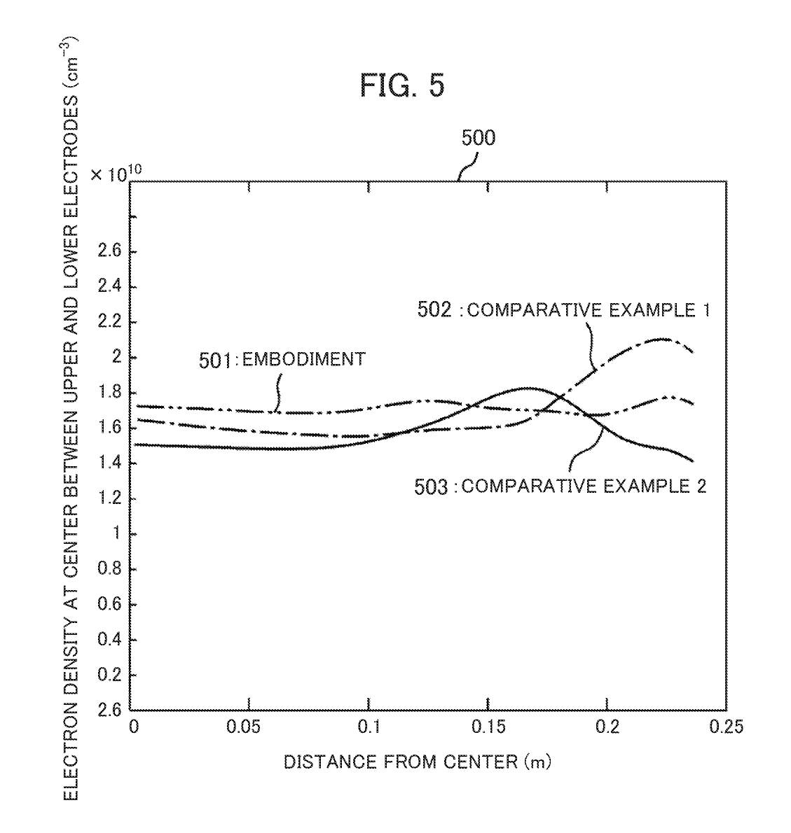

For comparison of the effects of this embodiment, FIG. 5 illustrates results of the comparisons of the analysis results of the electron density distribution in the case where the confinement plate 24 is not used (Comparative Example 1) and in the case where the confinement plate 24 is made of a conductor (Comparative Example 2) in the plasma processing apparatus 100 described in this embodiment. In FIG. 5, a radius of a wafer as the sample 3 is configured to be 150 mm (0.15 m), and the electron density distribution in a region up to 0.23 m outside the sample 3 is obtained.

From the results illustrated in FIG. 5, the case of Comparative Example 1, which does not use the confinement plate 24, increases the electron density as heading for the outer periphery and worsens the uniformity. Meanwhile, the case of Comparative Example 2, which uses the confinement plate 24 made of the conductor, increases the electron density at the region slightly close to the outer periphery where the confinement plate is installed and worsens the uniformity. In contrast to this, it is seen that the case of using the confinement plate 24 described in this embodiment exhibits the comparatively uniform electron density distribution in the region up to 0.23 m outside the sample 3.

It is considered that, in the case of Comparative Example 1, since the plasma volume at the outer peripheral portion of the sample stage 2 is large and heating efficiency by the magnetic field is high, the electron density of the plasma is likely to increase at the outer peripheral portion of the sample stage 2. It is considered that, in the case of Comparative Example 2, the confinement plate made of the conductor causes an electric field concentration at the confinement plate and therefore a local increase in the electron density occurs in the confinement plate.

According to this embodiment, the confinement plate 24 is disposed in the constant range with respect to the height of the sample (the wafer) 3 outside the sample (the wafer) 3 placed on the sample stage 2. This has ensured the comparatively uniformed electron density distribution of the plasma generated between the electrodes across the wide region outside the sample (the wafer) 3.

This has ensured the enhanced generation efficiency of the plasma and ensures improving the etching rate even with the identical input electric power. Additionally, since the region where the deposit accumulates is narrowed, the cleaning efficiency inside the chamber is enhanced, and the amount of foreign matter can be reduced. Further, since the electron density distribution on the sample (the wafer) 3 is uniformized, the uniformity of the etching rate distribution can be improved.

The invention made by the present inventor has been specifically described on the basis of the embodiments, the present invention is not limited to the above-described embodiments, and, needless to say, various changes can be made without departing from the scope of the present invention. For example, the embodiments described above are described in detail in order to facilitate understanding of the present invention, but the present invention is not limited to those having all the configurations described above. Other well-known configurations are added to a part of the configuration of the embodiments. The elimination and the substitution can also be performed.

What is claimed is:

1. A plasma processing apparatus comprising:
a processing chamber located inside a vacuum container, a plasma being formed in a depressurized inside of the processing chamber;
a sample stage located at a lower portion in the processing chamber, the sample stage having a top surface on which a sample as a process target is placed and held;
a circular plate-shaped upper electrode located inside the processing chamber above the top surface of the sample stage so as to be opposed to the top surface;
a shower plate disposed at a side of the upper electrode, the side facing the sample stage, the shower plate having a multitude of introduction holes to supply the inside of the processing chamber with a gas for processing;
an upper ring-shaped plate made of a dielectric, the upper ring-shaped plate being located on an outer peripheral side of the shower plate, the upper ring-shaped plate constituting a ceiling surface of the processing chamber; and
a first high-frequency power supply configured to apply a first high-frequency power to the upper electrode,
wherein the sample stage includes:
a circular plate-shaped or cylindrical lower electrode located inside the sample stage, a second high-frequency power being supplied to the circular plate-shaped or cylindrical lower electrode during processing the sample;
a susceptor ring made of a dielectric, the susceptor ring being located surrounding the top surface on an outer peripheral side of the top surface on which the sample is placed; and
a lower ring-shaped plate made of a dielectric, the lower ring-shaped plate being located at a position lower than a top surface of the susceptor ring on an outer peripheral side of the susceptor ring,
a distance between a top surface of the lower ring-shaped plate and a top surface of the sample in a height direction is set in a range of around 5 mm of a value found by a formula using a distance: G [mm] between the upper electrode and the lower electrode, a frequency: f [MHz] of the first high-frequency power, and a pressure: P [Pa] in the processing chamber, and −0.1×G−0.06×f−4.4×ln(P)+22 (Note that ln is a natural logarithm).

2. The plasma processing apparatus according to claim 1,
wherein the shower plate has a lower surface located at a position identical to a position of a lower surface of the upper ring-shaped plate in an up-down direction.

3. The plasma processing apparatus according to claim 1,
wherein a dielectric material constituting the lower ring-shaped plate has a relative permittivity of 80 or less.

4. The plasma processing apparatus according to claim 2,
wherein a dielectric material constituting the lower ring-shaped plate has a relative permittivity of 80 or less.

5. The plasma processing apparatus according to claim 1,
wherein the lower ring-shaped plate has a plurality of through-holes through which particles in the processing chamber above the sample stage pass.

6. The plasma processing apparatus according to claim 2,
wherein the lower ring-shaped plate has a plurality of through-holes through which particles in the processing chamber above the sample stage pass.

7. The plasma processing apparatus according to claim 1, further comprising a magnetic field generator located above or on an outer peripheral side of the vacuum container so as to surround the vacuum container, the magnetic field generator being configured to supply the inside of the processing chamber with a magnetic field.

8. The plasma processing apparatus according to claim 2, further comprising a magnetic field generator located above or on an outer peripheral side of the vacuum container so as to surround the vacuum container, the magnetic field generator being configured to supply the inside of the processing chamber with a magnetic field.

9. The plasma processing apparatus according to claim 1,
wherein the first high-frequency power has a frequency in a VHF band.

10. The plasma processing apparatus according to claim 2,
wherein the first high-frequency power has a frequency in a VHF band.

11. A plasma processing apparatus comprising:
a vacuum container;
a sample stage that includes a placement surface and a susceptor ring, the susceptor ring being made of a dielectric surrounding a peripheral area of the placement surface, a sample being placed on the placement surface at a lower portion inside the vacuum container;
an exhaust air unit configured to exhaust an air inside the vacuum container;
an upper electrode located at an upper portion inside the vacuum container opposed to the sample stage, the upper electrode having a peripheral area covered with an insulator; and
a high-frequency power application unit configured to apply a high-frequency power to the upper electrode,
wherein the plasma processing apparatus further comprises a ring-shaped plate at an outer peripheral portion of the susceptor ring of the sample stage, the ring-shaped plate is made of a dielectric material with a relative permittivity of 80 or less, the ring-shaped plate is positioned lower than a top surface of the sample placed on the placement surface of the sample stage in a height direction, and the ring-shaped plate is located at a position in the height direction such that a plasma with a density almost equivalent to a density at the top surface of the sample placed on the placement surface of the sample stage is formed when the high-frequency power is applied from the high-frequency power application unit to the upper electrode to generate a plasma at a space between the upper electrode and the sample stage inside the vacuum container.

12. The plasma processing apparatus according to claim 11,
wherein the ring-shaped plate has a plurality of holes or slits with a size to an extent that the plasma generated at the space between the upper electrode and the sample stage does not flow out.

13. The plasma processing apparatus according to claim 11,
wherein the ring-shaped plate is located at a position in the height direction such that a plasma with a distribution of an electron density of 10% or less is formed from the top surface of the sample placed on the placement surface of the sample stage to the ring-shaped plate when the high-frequency power is applied from the high-frequency power application unit to the upper electrode to generate the plasma at the space between the upper electrode and the sample stage inside the vacuum container.

14. The plasma processing apparatus according to claim 11,
wherein the ring-shaped plate is made of any of a quartz, an alumina, or an yttria.
